(19) United States
(12) Patent Application Publication
(10) Pub. No.: US 2012/0205668 A1
(43) Pub. Date: Aug. 16, 2012

(54) SWITCHING SEMICONDUCTOR DEVICES AND FABRICATION PROCESS

(76) Inventor: Atsuo WATANABE, Hitachiota (JP)

(21) Appl. No.: 13/454,335

(22) Filed: Apr. 24, 2012

Related U.S. Application Data
(63) Continuation of application No. 11/590,789, filed on Nov. 1, 2006, now abandoned.

(30) Foreign Application Priority Data
Nov. 1, 2005 (JP) JP2005-318454

(51) Int. Cl. H01L 29/78; H01L 29/24

(52) U.S. Cl. 257/77; 257/330; 257/E29.104; 257/E29.257

(57) ABSTRACT

A switching semiconductor device is provided, in which a negative gate voltage can be applied to the semiconductor device in an OFF state so as to increase a breakdown voltage of the gate junction without impairing a normally-off function of the semiconductor device and the ON-resistance. The switching semiconductor device is fabricated by using a semiconductor substrate with a band gap of 2.0 eV or more. In a JFET structure where a p⁺ type gate region and an n type source region are in contact so that a negative gate voltage can be applied, the p⁺ type gate region and an n⁺ type source region with a high impurity concentration are disposed with interposing an n type source region with an impurity concentration lower than that of the p⁺ type gate region and higher than that of a drift region of the JFET therebetween.

### CONTINUING DATA INFORMATION

The present application is a Continuation Application of U.S. application Ser. No. 11/590,789, filed Nov. 1, 2006, the content of which is hereby incorporated by reference into this application.

### FOREIGN PRIORITY DATA INFORMATION

The present application claims priority from Japanese Patent Application No. JP 2005-318454 filed on Nov. 1, 2005, the content of which is hereby incorporated by reference into this application.

### TECHNICAL FIELD OF THE INVENTION

The present invention relates to switching semiconductor devices. More particularly, it relates to a technology effectively applied to a power converter of a switching semiconductor device configured of a junction field effect transistor (JFET) fabricated by using a semiconductor substrate made of silicon carbide (SiC), diamond, gallium nitride (GaN), or the like with a wide band gap of 2 eV or more.

### BACKGROUND OF THE INVENTION

For example, in a power converter using a semiconductor device, it is required to downsize the power converter without decreasing conversion efficiency. For its achievement, a semiconductor device capable of a high-speed switching operation with low loss is indispensable. Thus, a switching semiconductor device made of silicon carbide (SiC), diamond, gallium nitride (GaN), or the like with a wide band gap of 2 eV or more has been under study. As a converter for processing large power of several tens of kW or more at high speed of several tens of kHz or more, a junction field effect transistor (hereinafter, referred to as JFET) having applied thereto an SiC substrate has been suggested.

For example, a sectional structure of an SiC-JFET disclosed in Japanese Patent Application Laid-Open Publication No. 2004-134547 (Patent Document 1) is shown in FIG. 15. In FIG. 15, a reference numeral 4 denotes an n⁺ type source region with a high impurity concentration formed on a first surface of an SiC substrate. 1 denotes an n⁺ type drain region with a high impurity concentration formed on the other surface, that is, a second surface of the SiC substrate. An n⁻ type drift region 2 with a low impurity concentration is formed between the source region 4 and the drain region 1 and adjacent to these regions. Trenches 33 are formed in the first surface of the SiC substrate, and adjacent trenches 33 form a mesa whose upper surface is the source region 4. A p⁺ type high impurity concentration layer is formed on the bottom surface of the trenches 33 and sidewalls of mesas, and it serves as a gate region 3. 31 denotes a gate electrode ohmic-connected to the gate region 3, 40 denotes a source electrode ohmic-connected to the source region 4, and 10 denotes a drain electrode ohmic-connected to the drain region 1.

In the high-speed switching operation of this semiconductor device, the voltage of the drain region 1 is abruptly changed. Therefore, a displacement current via a capacitance between the drain region 1 and the gate region 3 flows into the gate region 3 and the gate voltage is increased. In the JFET of FIG. 15, it is generally possible to sustain a state in which a current does not flow up to a rated value of the drain voltage unless the gate voltage exceeds a predetermined value (this is referred to as a threshold voltage), that is, an OFF state. However, as described above, when the gate voltage is increased due to a displacement current to exceed the threshold voltage, the semiconductor device is switched from an OFF state to an ON state in which a current flows with a low resistance, which results in an erroneous operation of the semiconductor device.

To avoid such an erroneous operation, a control scheme of applying a negative gate voltage when the semiconductor device is in an OFF state is applied. This is because, with such a negative gate voltage, an increase more than the threshold voltage can be avoided and an erroneous operation can be prevented.

However, in the conventional semiconductor device shown in FIG. 15, the p⁺ type gate region 3 and the n⁺ type source region 4 both with a high impurity concentration are in contact at a circled portion in FIG. 15. Therefore, a junction breakdown voltage is low, and a sufficient negative voltage cannot be applied to the gate region 3. For this reason, in the conventional semiconductor device, power conversion is limited to the one at low speed, which poses a problem in achieving the downsizing of the converter.

To get around this problem, for example, as a structural example to which a negative gate voltage can be applied, a technology disclosed in Published Japanese translation of PCT application No. 9-508492 (Patent Document 2) is known. This structure is shown in FIG. 16. This technology is different from the above-stated technology of FIG. 15 in that the p⁺ type gate region 3 formed on the sidewalls of the mesas is not in contact with but is separated from the n⁺ type source region 4 of the mesa portion (refer to a circled portion in FIG. 16). Since the p type region and the n type region both with a high impurity concentration are separated from each other, a junction breakdown voltage is high, and therefore a negative voltage can be applied to the gate.

### SUMMARY OF THE INVENTION

However, even in the technology disclosed in Patent Document 2 (FIG. 16), unnecessary voltage drop occurs in an ON state at the separation portion, that is, the n⁻ type low-concentration region. Therefore, a defect, that is, an increase in ON-resistance probably occurs. As described above, the problems in the above-described technologies are structural problems in which an increase in gate voltage occurs due to an abrupt change in drain voltage and an erroneous operation of switching to an ON state at the time of an OFF state caused by this increase in gate voltage cannot be solved by applying a negative gate voltage to the gate region.

Also, for example, a structure as shown in FIG. 17 is also suggested. This structure is different from that of the technology of FIG. 15 described above in that p type gate regions 35 formed on the sidewalls of the mesas and p⁺ type gate regions 36 at the bottoms of the trenches have different impurity concentrations and the impurity concentration of the p type gate regions 35 on the sidewalls of the mesas is lower than that of the p⁺ type gate regions 36 at the bottoms. However, although the breakdown voltage can be improved by reducing the concentration of a portion of the p type gate region 35 in contact with the n⁺ type source region 4 of the mesa portion, a depletion layer is increased in the p type gate region 35. Accordingly, the depletion layer extending to the n⁻ type drift region 2 of the channel region is shortened, which impairs a normally-off function of the JFET.

Therefore, an object of the present invention is to provide a switching semiconductor device in which, in order to avoid an erroneous operation of a JFET even when gate potential is increased due to noise, a breakdown voltage of the gate junction is increased without impairing a normally-off function of the semiconductor device and the ON-resistance so as to apply a negative gate voltage to the semiconductor device in an OFF state.

The above and other objects and novel characteristics of the present invention will be apparent from the description of this specification and the accompanying drawings.

Typical embodiments of the inventions disclosed in this application will be briefly described as follows.

A main feature of the present invention lies in that, in a JFET structure where a p⁺ type gate region and an n type source region are in contact so that a negative gate voltage can be applied, the p⁺ type gate region and an n⁺ type source region with a high impurity concentration are placed with interposing an n type source region with an impurity concentration lower than that of the p⁺ type gate region and higher than that of a drift region of the JFET therebetween.

The effects obtained by typical aspects of the present invention will be briefly described below.

According to the present invention, with the p⁺ type gate region with a high impurity concentration being kept unchanged, the impurity concentration of the source regions in contact with the p⁺ type gate region is decreased within a range where the ON-resistance is not impaired. Therefore, without impairing the normally-off function of the semiconductor device and the ON-resistance, the breakdown voltage of the gate junction can be increased. Accordingly, the negative gate voltage can be applied to the semiconductor device in an OFF state, and the OFF state can be maintained without an erroneous operation even when the gate potential is fluctuated due to a noise current. Furthermore, since the threshold voltage can be reduced without decreasing noise tolerance, the ON-resistance can be further reduced. Consequently, an effect of improving both reliability and characteristic can be achieved.

### BRIEF DESCRIPTIONS OF THE DRAWINGS

FIG. 1 is a sectional view of a switching semiconductor device according to a first embodiment of the present invention;

FIG. 2 is a drawing showing a distribution of an impurity concentration in a depth direction along a dotted line a-a′ in the switching semiconductor device according to the first embodiment of the present invention;

FIG. 3 is a sectional view of a switching semiconductor device according to a second embodiment of the present invention;

FIG. 4 a drawing showing a distribution of an impurity concentration in a depth direction along a dotted line a-a′ in the switching semiconductor device according to the second embodiment of the present invention;

FIG. 5 is a sectional view of a switching semiconductor device according to a third embodiment of the present invention;

FIG. 6 is a sectional view of a switching semiconductor device according to a fourth embodiment of the present invention;

FIG. 7A is a sectional view showing a process of a method of fabricating the switching semiconductor device according to the first embodiment of the present invention;

FIG. 7B is a sectional view (continued from FIG. 7A) showing a process of a method of fabricating the switching semiconductor device according to the first embodiment of the present invention;

FIG. 7C is a sectional view (continued from FIG. 7B) showing a process of a method of fabricating the switching semiconductor device according to the first embodiment of the present invention;

FIG. 8A is a sectional view (continued from FIG. 7C) showing the process of the method of fabricating the switching semiconductor device according to the first embodiment of the present invention;

FIG. 8B is a sectional view (continued from FIG. 8A) showing the process of the method of fabricating the switching semiconductor device according to the first embodiment of the present invention;

FIG. 8C is a sectional view (continued from FIG. 8B) showing the process of the method of fabricating the switching semiconductor device according to the first embodiment of the present invention;

FIG. 9A is a sectional view (continued from FIG. 8C) showing the process of the method of fabricating the switching semiconductor device according to the first embodiment of the present invention;

FIG. 9B is a sectional view (continued from FIG. 9A) showing the process of the method of fabricating the switching semiconductor device according to the first embodiment of the present invention;

FIG. 9C is a sectional view (continued from FIG. 9B) showing the process of the method of fabricating the switching semiconductor device according to the first embodiment of the present invention;

FIG. 10A is a sectional view showing a process of a method of fabricating the switching semiconductor device according to the second embodiment of the present invention;

FIG. 10B is a sectional view (continued from FIG. 10A) showing a process of a method of fabricating the switching semiconductor device according to the second embodiment of the present invention;

FIG. 10C is a sectional view (continued from FIG. 10B) showing a process of a method of fabricating the switching semiconductor device according to the second embodiment of the present invention;

FIG. 11 is a sectional view (continued from FIG. 10C) showing the process of the method of fabricating the switching semiconductor device according to the second embodiment of the present invention;

FIG. 12 is a layout plan view of the switching semiconductor device according to the first to fourth embodiments of the present invention;

FIG. 13 is another layout plan view of the switching semiconductor device according to the first to fourth embodiments of the present invention;

FIG. 14 is a circuit diagram of a drive circuit of the switching semiconductor device according to the first to fourth embodiments of the present invention;

FIG. 15 is a sectional view of a switching semiconductor device according to a conventional technology;

FIG. 16 is a sectional view of another switching semiconductor device according to the conventional technology; and

FIG. 17 is a sectional view of a switching semiconductor device showing a proposed measure for solving a problem in the conventional technology.

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiment, and the repetitive description thereof will be omitted.

### Concept of Embodiments of the Present Invention

The switching semiconductor device according to embodiments of the present invention is achieved by forming an n type source region so as to have a multilayered structure of a high impurity concentration layer on its main surface side and a low impurity concentration layer with a predetermined concentration lower than that of the high impurity concentration layer through a normal ion implantation technology and processing them into a mesa shape with a predetermined width, and then forming a gate region with a high impurity concentration on the sidewalls of the mesa again through the ion implantation technology.

### First Embodiment

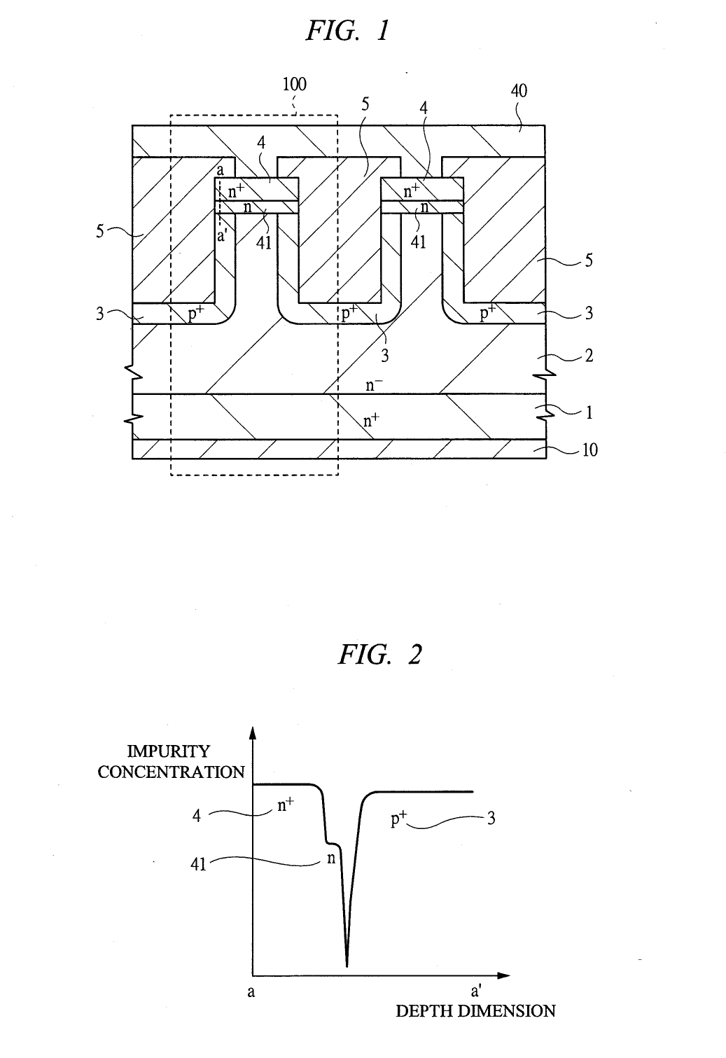

FIG. 1 is a sectional view of a switching semiconductor device according to a first embodiment of the present invention. The switching semiconductor device according to this embodiment is fabricated by using a semiconductor substrate having opposing first and second surfaces and a band gap of 2.0 eV or more. The switching semiconductor device includes: an n⁺ type source region 4 with a high impurity concentration extending to the first surface in this semiconductor substrate; an n⁺ type drain region 1 with a high impurity concentration extending to the second surface in this semiconductor substrate; an n⁻ type drift region 2 with a lower impurity concentration than those of the source region 4 and the drain region 1, which is adjacently formed between the source region 4 and the drain region 1 in the semiconductor substrate; a trench 5 formed to extend to the first surface in this semiconductor substrate; and a p⁺ type gate region 3 with a high impurity concentration, which defines a mesa including the source region 4 between adjacent trenches 5 and is formed to extend to the bottom portion of the trench 5 and the sidewalls of the mesa. A portion of the source region 4 in contact with the gate region 3 formed on the sidewalls of the mesa is an n type region having an impurity concentration lower than that of the source region 4 extending to the first surface and also lower than that of the gate region 3, but higher than that of the drift region 1.

More specifically, the gate region 3 formed on the sidewalls of the mesa is formed in contact with the source region on the bottom surface of the source region. This source region includes a lower first source region 41 in contact with the gate region 3 and an upper second source region 4 formed and laminated on the first source region 41. The second source region 4 is a high impurity concentration region and the first source region 41 is a predetermined low impurity concentration region. Also, the gate region 3 is a p type high impurity concentration region formed on the sidewalls of the mesa.

A distribution of the impurity concentration in a depth direction along a dotted line a-a′ in the switching semiconductor device of FIG. 1 is shown in FIG. 2. In FIG. 2, the source region 41 has an impurity concentration lower than those of the source region 4 and the gate region 3. The predetermined impurity concentration is set lower than that of the source region 4 by one order of magnitude at most. As shown in FIG. 2, since the n type source region 41 in contact with the gate region 3 is a low impurity concentration region, the junction breakdown voltage of this structure is increased by approximately one order of magnitude compared with the case where the gate region 3 and the source region 4 are directly in contact with each other. Also, since the source region 41 has a thickness smaller than the source region 4 as shown in FIG. 2, even when a current flows through this source region, a voltage drop is not so problematic, and therefore an adverse effect on the ON-resistance can be prevented.

### Second Embodiment

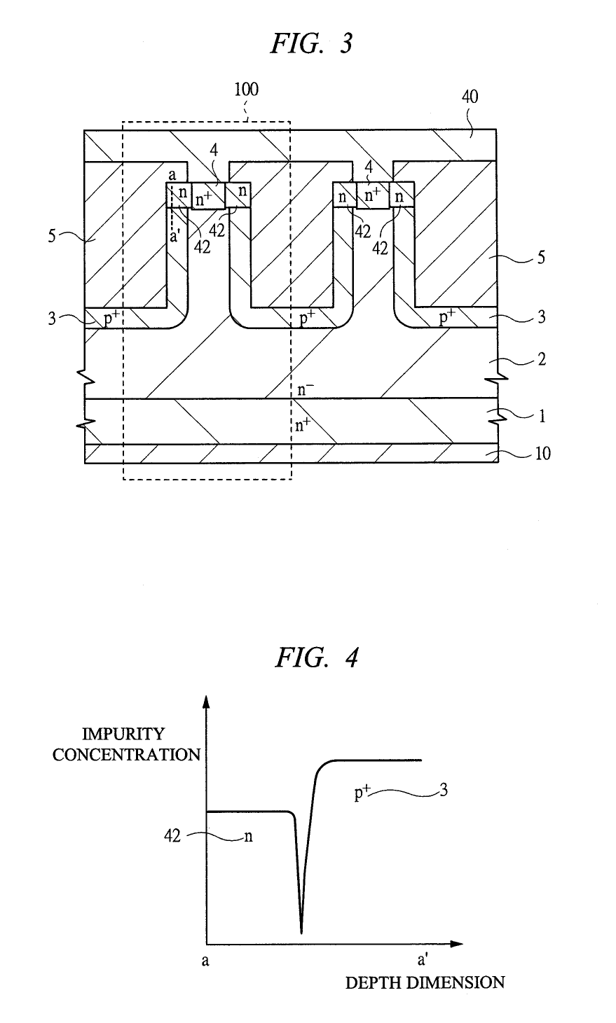

FIG. 3 is a sectional view of a switching semiconductor device according to a second embodiment of the present invention. In the switching semiconductor device according to this embodiment, a source region 42 with a low impurity concentration is provided around the source region 4 with a high impurity concentration, and a main region through which a current flow is the n⁺ type source region 4 with a high impurity concentration. Therefore, in this embodiment, a semiconductor device with a lower ON-resistance compared with the first embodiment can be achieved.

More specifically, the source region includes: n type source regions 42 distributed into a plurality of island regions each surrounded by and in contact with the gate region 3 and having an impurity concentration lower than that of the gate region 3 and higher than that of the drift region 2 at portions in contact with the gate region 3; and the source region 4 adjacent to this source region 42 and having an impurity concentration further higher than that of the source region 42 and higher than those of the gate region 3 and the drain region 1.

A distribution of the impurity concentration in a depth direction along a dotted line a-a′ in the switching semiconductor device of FIG. 3 is shown in FIG. 4. In FIG. 4, the source region 42 has an impurity concentration lower than that of the gate region 3.

### Third Embodiment

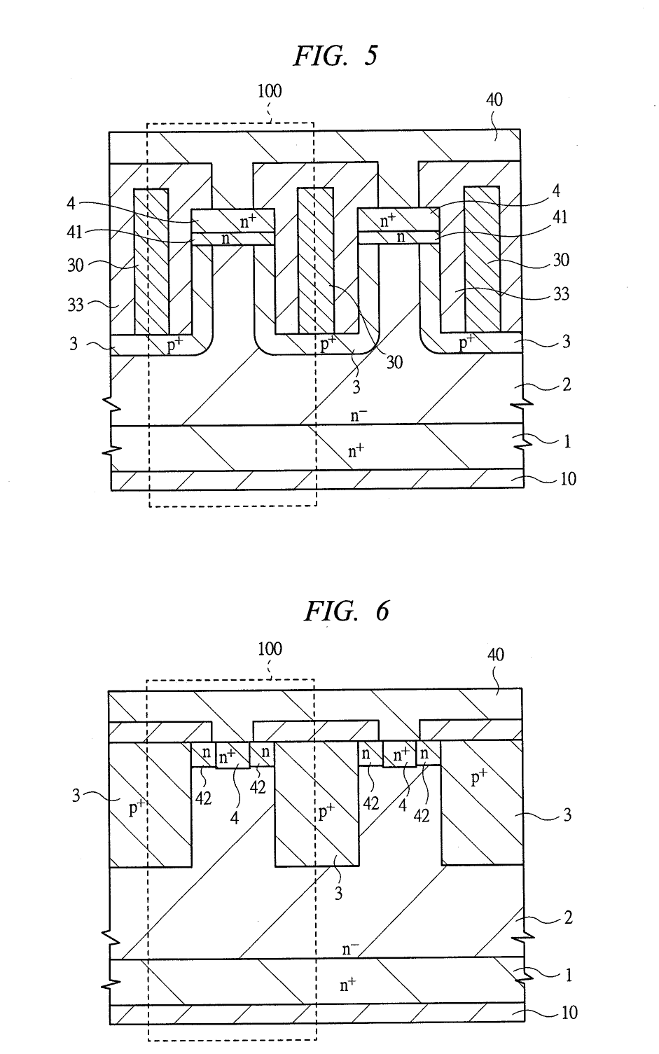

FIG. 5 is a sectional view of a switching semiconductor device according to a third embodiment of the present invention. In the switching semiconductor device according to this embodiment, a low-resistant gate electrode 30 ohmic-connected to the p⁺ type gate region 3 provided at the bottom of the trench 33 is formed in a plug shape so as to fill the trench 33. This gate electrode 30 is preferably formed of tungsten W, molybdenum Mo, aluminum Al, nickel Ni, or a compound thereof. Alternatively, the gate electrode 30 can be formed of a low-resistant polysilicon. By this means, since the p⁺ type gate region 3 is shunted by the low-resistant gate electrode 30, gate resistance components viewed from the gate terminal of the semiconductor device (not shown) are significantly reduced. Accordingly, in this semiconductor device, the voltage fluctuation due to a noise current of the p⁺ type gate region 3 can be easily suppressed by using a negative gate voltage applied from the gate circuit to the gate terminal, and an erroneous operation can be further reduced.

Also, the semiconductor device according to this embodiment has a structure in which many unit cells 100 are connected in parallel for operation. Therefore, since the respective unit cells are connected in parallel with the low-resistant gate electrodes 30, parallel operations uniformly occur and a power converter capable of controlling a large amount of power can be achieved.

### Fourth Embodiment

FIG. 6 is a sectional view of a switching semiconductor device according to a fourth embodiment of the present invention. In the switching semiconductor device according to this embodiment, in a unit cell, the p⁺ type gate region 3 is placed outside of the source regions 4 and 42, and the p⁺ type gate region 3 extends to one of main surfaces of the semiconductor substrate. Since the main surface is flat without a concave portion such as a trench, the source electrodes 40 can be easily formed. Also, since the p⁺ type gate region 3 can be formed through epitaxial growth scheme, effects such as accurately determining the position of a p-n junction, easily reducing the resistance of the gate region, and easily reducing the width of the gate region can be achieved.

### Method of Fabricating the First Embodiment)

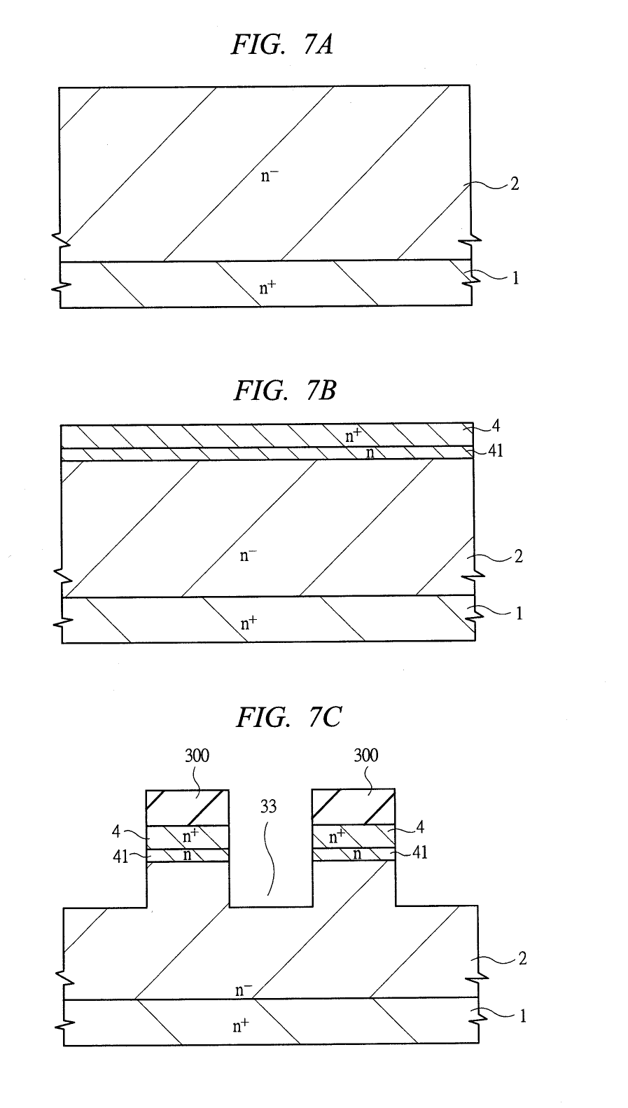

FIGS. 7A to 7C, 8A to 8C, and 9A to 9C are sectional views showing the process of fabricating the switching semiconductor device according to the above-described first embodiment shown in FIG. 1. In this embodiment, a fabrication method where a 4H crystalline polymorphism silicon carbide (4H—SiC) with a band gap of 3.02 eV is used as a semiconductor substrate will be described. Note that reference numerals in parentheses represent those corresponding to components shown in FIG. 1.

In FIG. 7A, an n⁺ type 4H—SiC substrate (1) doped with an n type impurity of nitride with a high concentration is prepared. On its one surface, an n⁻ layer (2) with a low impurity concentration is formed through an epitaxial growth so as to be controlled to have a predetermined n type impurity concentration. In this embodiment, the predetermined concentration is set to be 2×10¹⁶/cm³ in terms of carrier concentration. A portion denoted by 1 serves as a drain region, and a portion denoted by 2 serves as a drift region.

In FIG. 7B, a low impurity concentration layer (41) and a high impurity concentration layer (4) are formed on one surface of the n⁻ layer (2) through an ion implantation process. The layer denoted by 41 has an impurity concentration of about 10¹⁸ to 10¹⁹/cm³ and the layer denoted by 4 has an impurity concentration of about 10²°/cm³. These n type layers serve as source regions.

In FIG. 7C, an oxide film 300 is formed through CVD near the n⁺ type source region 4 and is then processed into a strip shape with a predetermined width through optical lithography and dry etching. Furthermore, with using the patterned oxide film 300 as a mask, the n⁺ layer, the n layer, and the n⁻ layer below the oxide film 300 is subjected to dry etching to form a trench 33 having vertical side surfaces. In this embodiment, the trench is designed to have a width of 0.9 to 1.1 μm and a depth of 1.0 to 1.5 μm. However, these dimensions have optimal values depending on a rated voltage of each semiconductor device, and therefore it is most suitable that these dimensions are respectively determined through designing and prototype manufacturing.

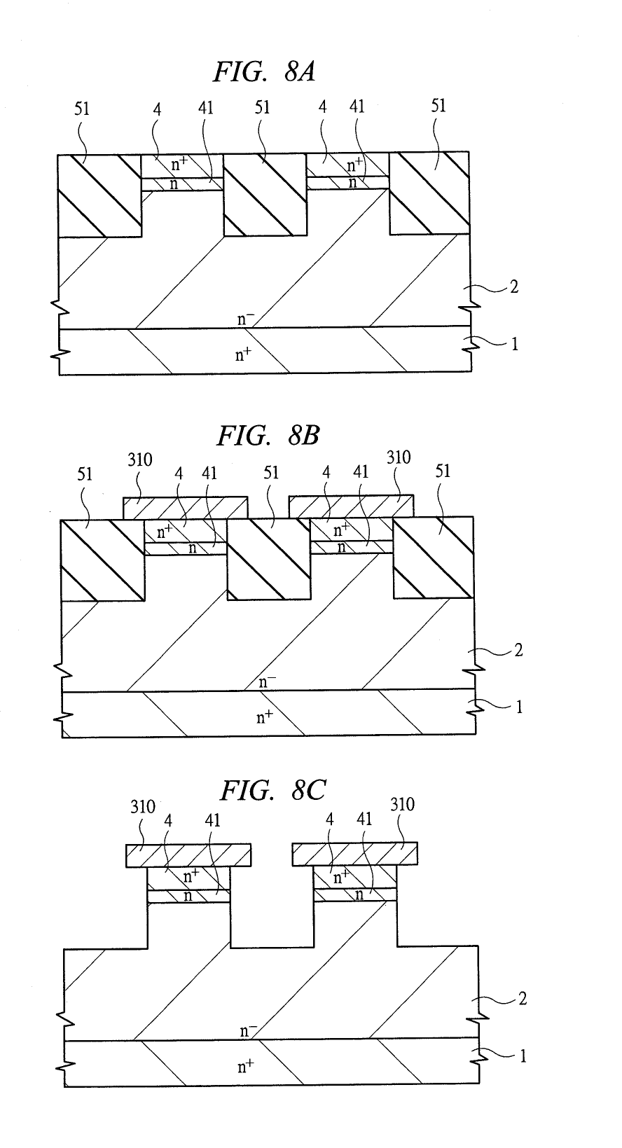

In FIG. 8A, after the oxide film 300 is removed, an oxide film 51 is formed again through CVD at the trench portion and is then polished so that its surface is planarized.

In FIG. 8B, a polysilicon film 310 is formed on the planarized surface through CVD and is then processed so as to have a shape of covering the source region with constant and uniform dimensions.

In FIG. 8C, when the oxide film 51 is removed, the polysilicon film 310 which covers the source region in an overhanging manner can be formed.

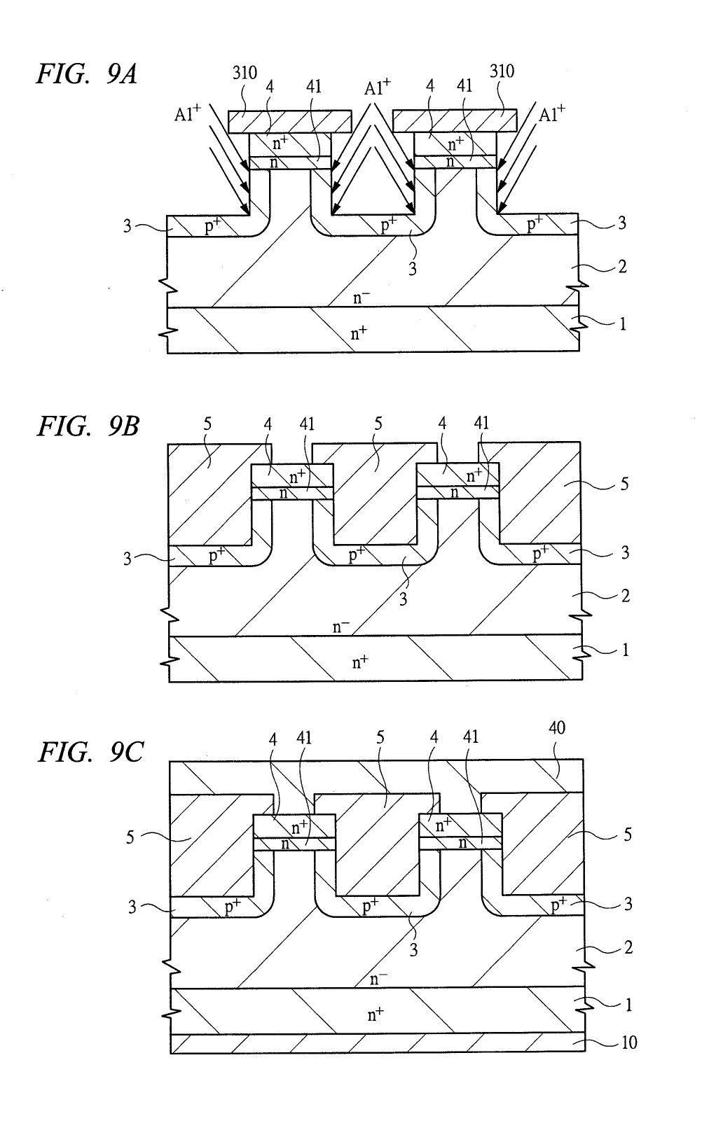

In FIG. 9A, when aluminum (Al) ions are implanted on a tilt with using the polysilicon film 310 as a mask, p⁺ type regions are formed on the sidewalls of the mesa. At this time, in the upper surface of the mesa not exposed due to the overhanging polysilicon film 310, that is, in the n type source region 41, Al ions are not implanted to the sidewalls of the mesa. Therefore, even when Al ions with a high concentration are implanted, the n type region with a low concentration does not disappear.

In FIG. 9B, the mask of the polysilicon film 310 for ion implantation is removed, an oxide film (5) is formed again on the entire surface, and then a contact hole is opened in the source region 4. The contact hole has a width of 0.5 μm.

In FIG. 9C, electrodes are formed on the opposing surfaces of the source surface and the drain surface. More specifically, a source electrode 40 and a drain electrode 10 are formed. By doing so, a semiconductor device is completed. In practice, however, processes normally required for semiconductor devices such as an end-face process and formation of a gate terminal, a gate electrode, and a passivation region of the semiconductor device have to be performed, but these processes are omitted in the drawings.

### Method of Fabricating the Second Embodiment

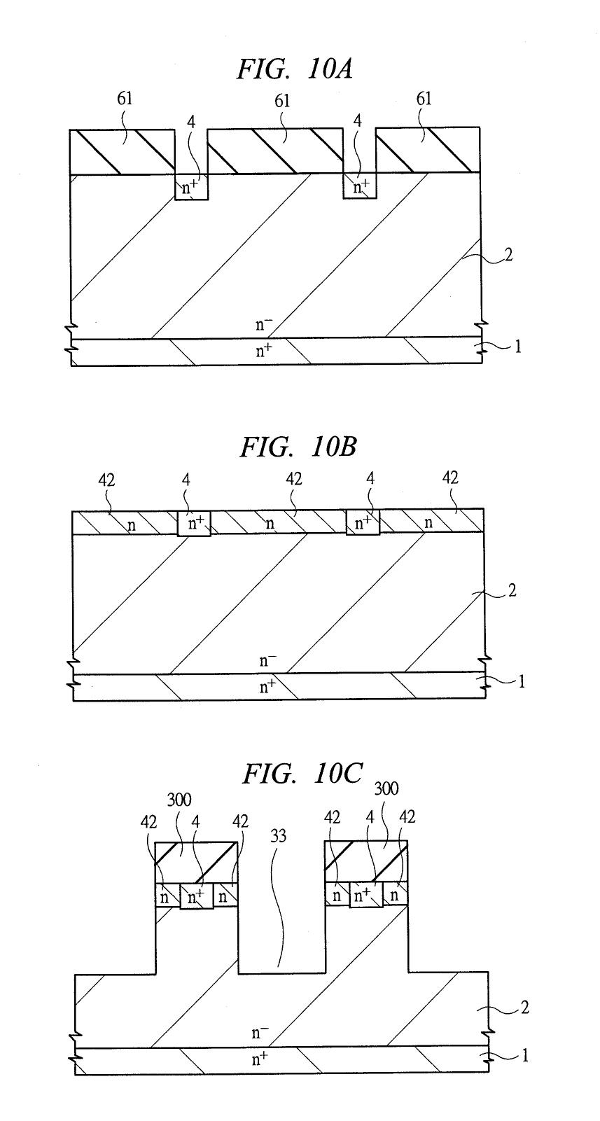

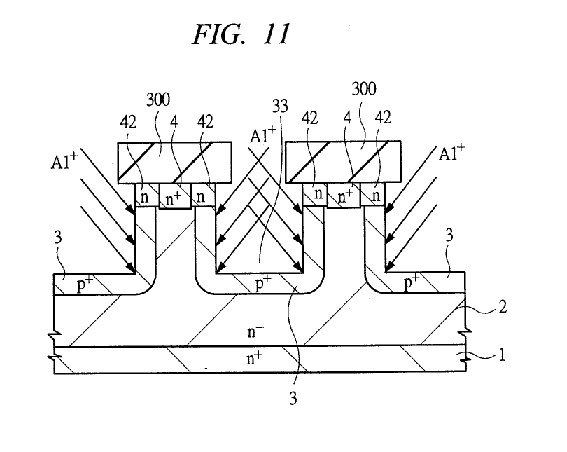

FIGS. 10A to 10C and FIG. 11 are sectional views showing the process of fabricating the switching semiconductor device according to the above-described second embodiment shown in FIG. 3. In this embodiment, a fabrication method where a 4H crystalline polymorphism silicon carbide (4H—SiC) with a band gap of 3.02 eV is used as a semiconductor substrate will be described. Note that reference numerals in parentheses represent those corresponding to components shown in FIG. 3.

In FIG. 10A, a 4H—SiC substrate having an n⁻ type epitaxial layer (2) with a low impurity concentration laminated on an n⁺ high impurity concentration substrate (1) is prepared. On its one surface, an oxide film 61 is formed and then an opening is formed therein. With using the oxide film 61 as a mask for selective formation by ion implantation, an n⁺ high impurity concentration region (4) is formed.

In FIG. 10B, after the mask of the oxide film 61 for selective formation is removed, nitrogen is ion-implanted in the entire surface, thereby forming n type regions (42) with a low impurity concentration in the regions other than the n⁺ high impurity concentration region (4).

In FIG. 10C, an oxide film 300 is processed and formed so as to cover the n⁺ type region (4) and the n type regions (42) surrounding the n⁺ type region with predetermined dimensions. Next, with using this oxide film 300 as a mask, the SiC substrate is processed under anisotropic dry etching conditions in a vertical direction to form a trench 33 and mesas. In this embodiment, the trench and the mesa are designed to have a width of approximately 1 μm. However, it is preferable that the dimension is optimally changed according to the standard of the microfabrication technology to be applied.

In FIG. 11, when etching is performed with using the oxide film 300 as a mask for a predetermined time by switching the dry etching conditions of the SiC substrate to isotropic dry etching conditions, an overhang shape where the sidewalls of the mesa of SiC are located inwardly from the oxide film by about 0.15 to 0.2 μm is formed. Then, Al ions are implanted to the sidewalls through tilt ion implantation, thereby forming a p⁺ type gate region 3 on the bottom surface of the trench and the sidewalls of the mesa. Furthermore, after an oxide film filling the trench 5, a contact opening on the source, the source electrode 40, and the drain electrode 10 are formed, the semiconductor device is completed.

### Flat Pattern According to the First to Fourth Embodiments

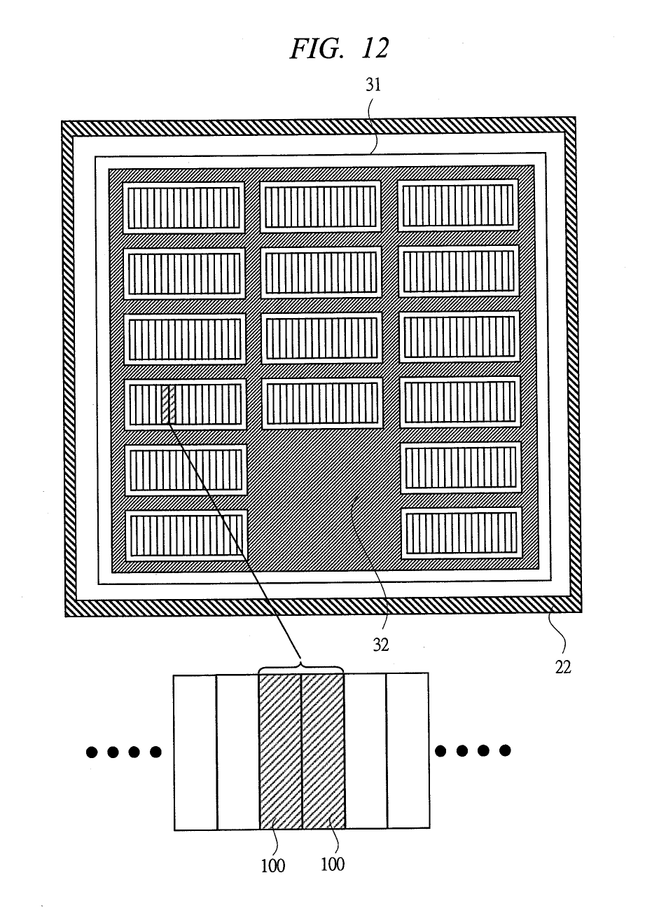

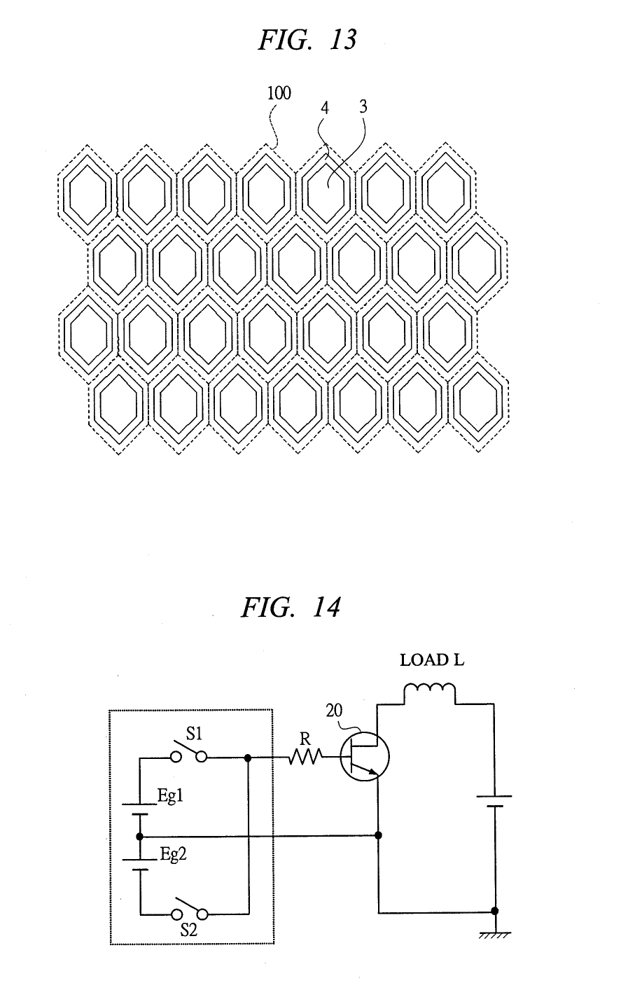

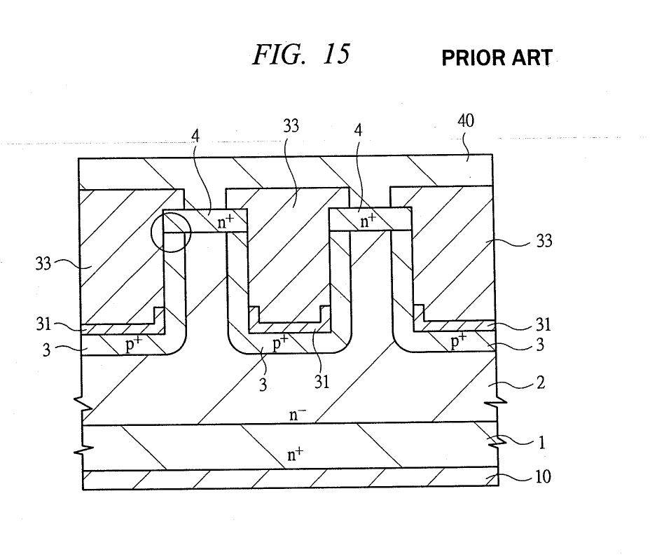

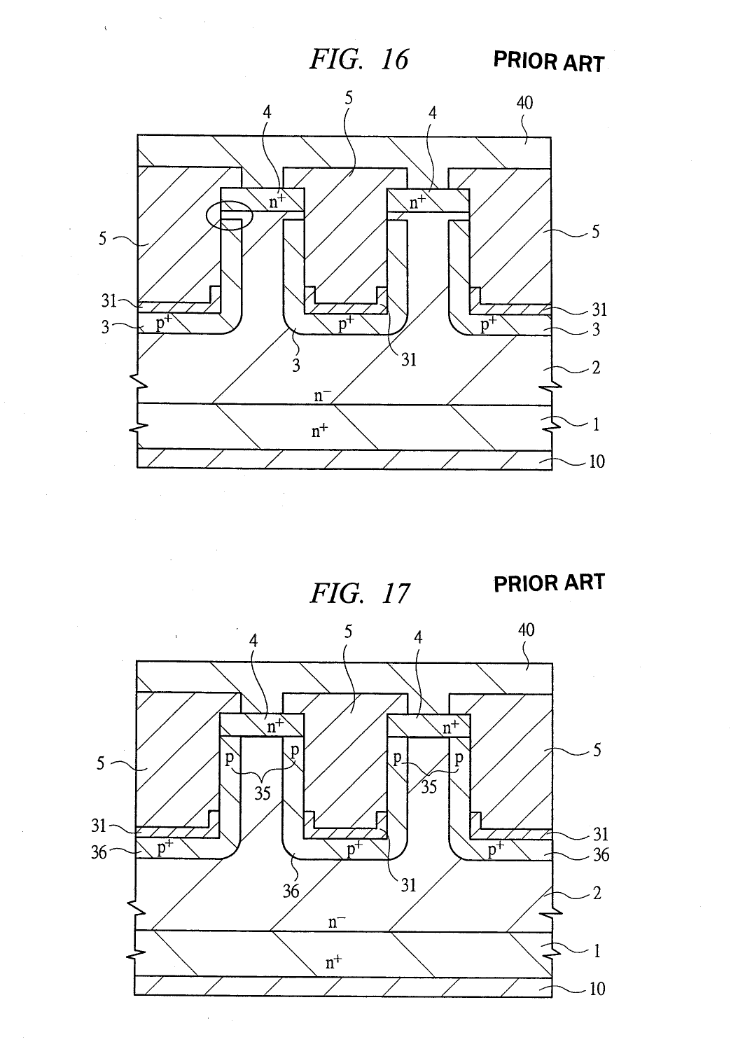

FIG. 12 is a layout plan view (flat pattern) of the switching semiconductor device according to the above-described first to fourth embodiments shown in FIGS. 1, 3, 5, and 6. In FIG. 12, fine rectangular regions represent the unit cells 100 shown in the respective sectional views of FIGS. 1, 3, 5, and 6. These many unit cells 100 are disposed according to the rated current capacity of the semiconductor device.

Also, these unit cells 100 form several sub-units. In FIG. 12, 32 denote a gate electrode ohmic connected to the p⁺ type gate region 3. This gate electrode 32 is disposed so as to surround the sub-units so that a gate resistance between sub-units becomes uniform and low resistance. 31 denotes a terminated region of a p type gate region. 22 denotes an n⁺ type region, which is so-called a channel-cut region, provided on the further periphery to prevent the spread of a parasitic channel.

FIG. 13 is another layout plan view (flat pattern) different from that of FIG. 12. Unlike the rectangular unit cells shown in FIG. 12, hexagonal unit cells 100 are disposed on the plane. With this layout, the density of the disposed unit cells 100 can be increased, and the chip area can be reduced.

### Drive Circuit in the First to Fourth Embodiments

FIG. 14 is a circuit diagram of a drive circuit of the switching semiconductor device according to the above-described first to fourth embodiments shown in FIGS. 1, 3, 5, and 6. To turn on the switching semiconductor device 20 according to each embodiment, a positive voltage Eg1 is applied to a gate terminal. To turn off, a negative voltage, that is, a voltage Eg2 is applied to achieve a stable and reliable operation. In these embodiments, the negative voltage is preferably selected from a range of −5 V to −20 V.

As described above, according to each of the above-described embodiments, with the p⁺ type gate region 3 with a high impurity concentration being kept unchanged, the impurity concentration of the source regions 41 and 42 in contact with the p⁺ type gate region 3 is decreased within a range where the ON-resistance is not impaired. Therefore, the breakdown voltage of the gate junction can be increased without impairing the normally-off function of the semiconductor device and the ON-resistance. Thus, the negative gate voltage can be applied to the semiconductor device in an OFF state, and the OFF state can be maintained without an erroneous operation even when the gate potential is fluctuated due to a noise current.

Furthermore, since the threshold voltage can be reduced without decreasing noise tolerance, the ON-resistance can be further reduced. Accordingly, an effect of improving both reliability and characteristics can be achieved.

In the foregoing, the invention made by the inventors of the present invention has been concretely described based on the embodiments. However, it is needless to say that the present invention is not limited to the foregoing embodiments and various modifications and alterations can be made within the scope of the present invention.

For example, in each of the above-described embodiments, the switching semiconductor device to which a 4H—SiC semiconductor substrate is applied has been described. Alternatively, another SiC substrate can be applied. For example, a 6H type or 3C type substrate with a different crystalline polymorphism may be applied. Furthermore, a semiconductor substrate other than SiC such as diamond, gallium nitride (GaN), or aluminum nitride (AlN) may be applied.

What is claimed is:

1. A semiconductor device, comprising:
a drain region of a first conductivity type;
a drift region of the first conductivity type formed over the drain region;
a source region of the first conductivity type formed over the drift region;
a trench formed in the source region and the drift region;
an insulating film formed in the trench; and
a gate region of a second conductivity type, opposite to the first conductivity type, formed in the drift region so as to surround a bottom of the trench and a sidewall of the trench,
wherein the source region includes a first source region and a second source region formed under the first source region,
wherein an impurity concentration of the second source region is lower than an impurity concentration of the first source region, and
wherein, at the sidewall of the trench, the gate region is connected to the second source region.

2. A semiconductor device according to the claim 1,
wherein a thickness of the second source region is smaller than a thickness of the first source region.

3. A semiconductor device according to the claim 2,
wherein the impurity concentration of the second source region is higher than an impurity concentration of the drift region.

4. A semiconductor device according to the claim 3,
wherein the drain region is made of an SiC substrate.

5. A semiconductor device according to the claim 1,
wherein the impurity concentration of the second source region is higher than an impurity concentration of the drift region.

6. A semiconductor device according to the claim 1,
wherein the drain region is made of an SiC substrate.

7. A semiconductor device according to the claim 1,
wherein the semiconductor device is a switching semiconductor device.

8. A semiconductor device according to the claim 1,
wherein the insulating film is also formed over the first source region such that a part of the first source region is exposed from the insulating film,
wherein a source electrode is formed on the exposed first source region, and
wherein a drain electrode is formed under the drain region.

9. A semiconductor device according to the claim 1,
wherein the first conductivity type is n type, and
wherein the second conductivity type is p type.
